(19) United States
(12) Patent Application Publication
(10) Pub. No.: US 2014/0160702 A1
(43) Pub. Date: Jun. 12, 2014

(54) MOUNTING APPARATUS FOR EXPANSION CARDS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: Yu-Wei HE, Shenzhen (CN); Xiu-Quan HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/948,114

(22) Filed: Jul. 22, 2013

(30) Foreign Application Priority Data
Dec. 11, 2012 (CN) 2012105303976

(51) Int. Cl. H05K 7/14

(52) U.S. Cl. CPC H05K 7/1417
USPC 361/759

(57) ABSTRACT

A mounting apparatus includes a mounting case, a mounting piece attached to a front end of an expansion card, and a securing member. The mounting case includes a front plate and a rear plate. A stopper piece is located on the rear plate. The mounting piece is secured to the front plate. The securing member is slidably attached to the rear plate and includes a limiting piece. The securing member is slidable relative to the rear plate in a direction that is substantially parallel to the rear plate, and the limiting piece and the stopper piece sandwich a rear end of the expansion card.

### BACKGROUND

1. Technical Field

The present disclosure relates to mounting apparatuses, and particularly to a mounting apparatus for securing expansion cards in an electronic device.

2. Description of Related Art

Computer systems usually include multiple expansion cards, such as sound cards, video cards, graphics cards and so on, for enhancing capabilities of the computer system. Long expansion cards may be coupled to a circuit board and secured at only one end to a front wall of a computer system enclosure, which may not provide enough stability, particularly during transportation of the computer system. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of a mounting apparatus and an expansion card in accordance with an embodiment.

FIG. 2 is similar to FIG. 1, but viewed from a different aspect.

FIG. 3 is an exploded, isometric view of a securing member of the mounting apparatus of FIG. 1.

FIG. 4 is an assembled view of the mounting apparatus and the expansion card of FIG. 1, and a protrusion of a mounting case of the mounting apparatus is located in a guiding portion of a sliding slot of the securing member.

FIG. 5 is similar to FIG. 4, but viewed from a different aspect.

FIG. 6 is similar to FIG. 4, and the protrusion is located in a receiving portion of the sliding slot.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

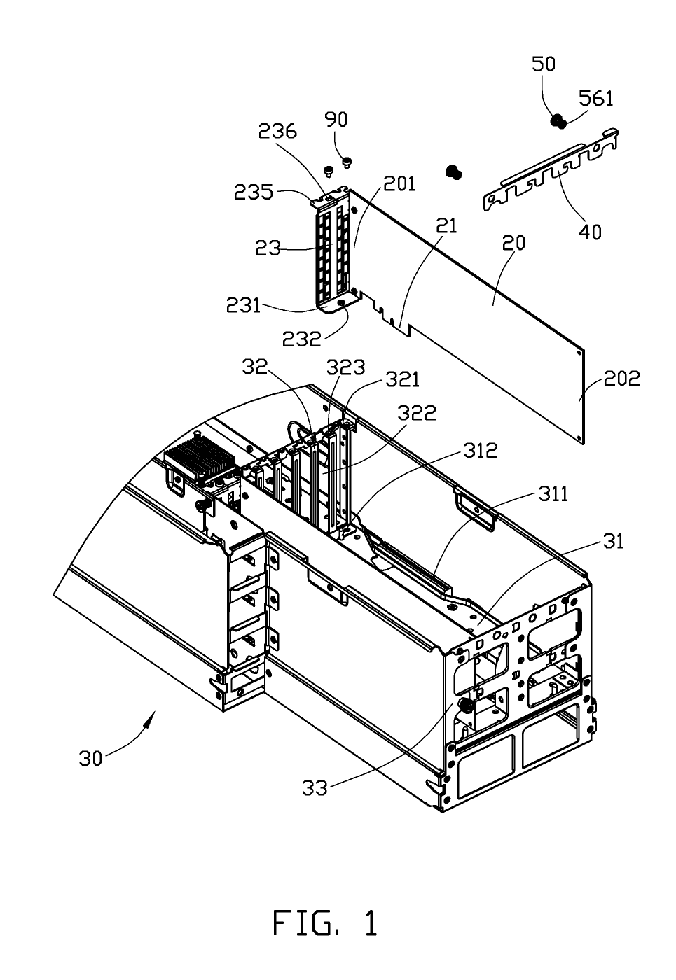

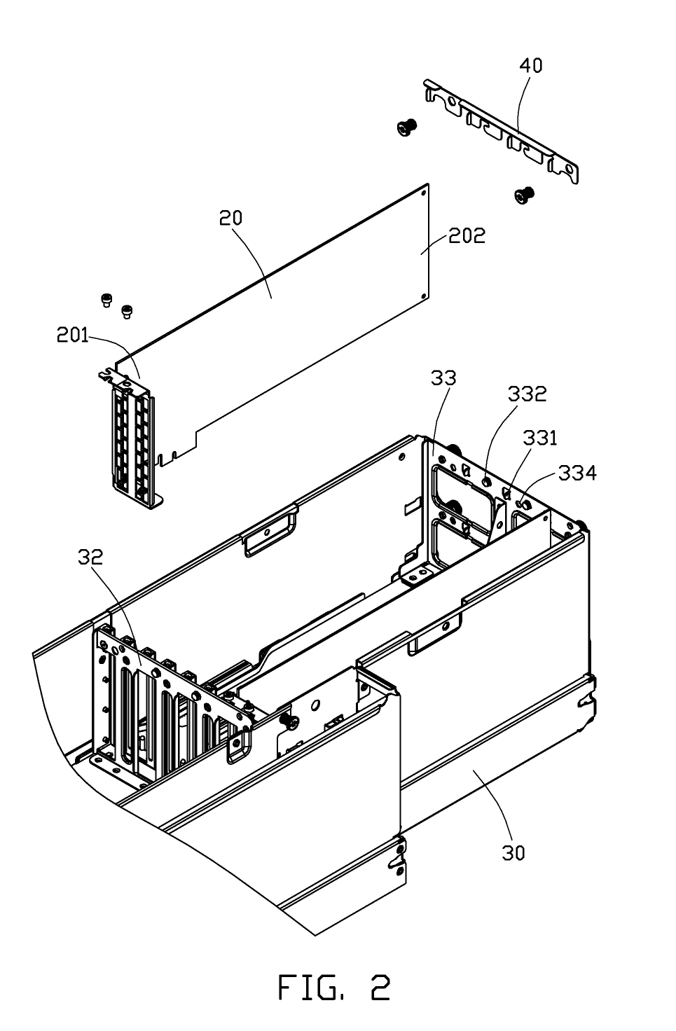

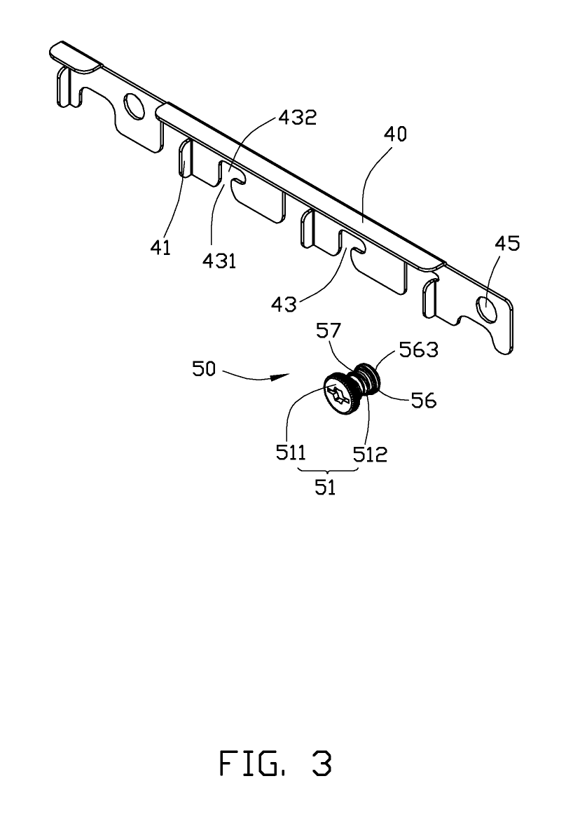

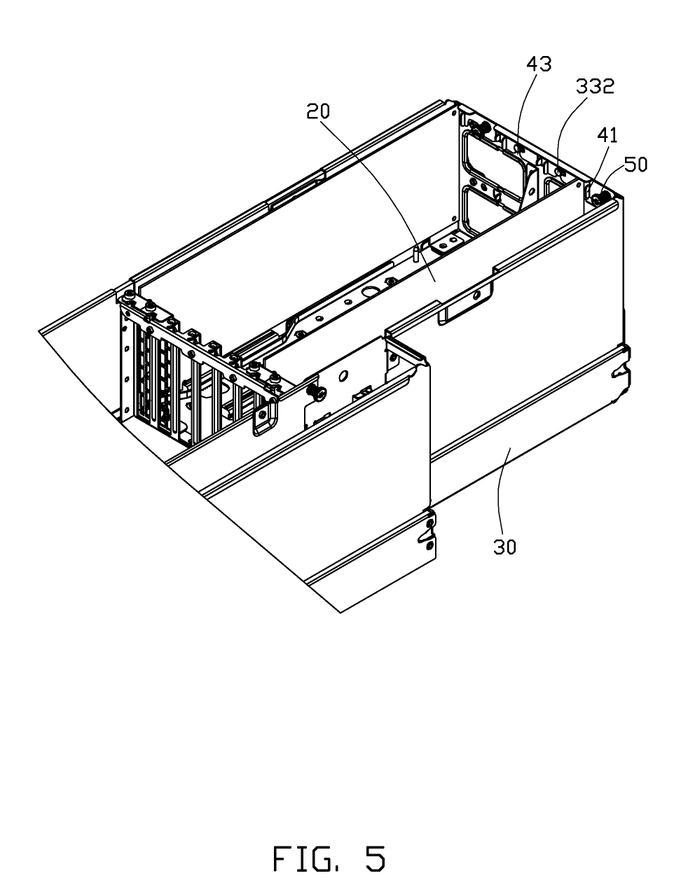

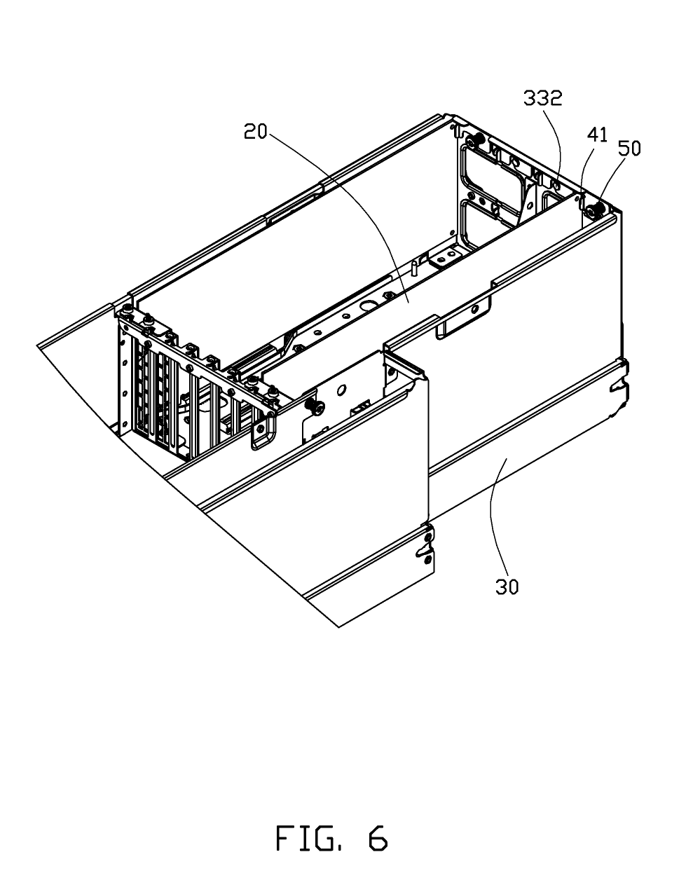

FIGS. 1-3 illustrate a mounting apparatus in accordance with an embodiment for securing a plurality of expansion cards 20 (only one is shown in FIGS. 1-6). In one embodiment, the expansion cards 20 may be, for example, sound cards, video cards, graphics cards, or other peripheral component interconnection cards.

Each expansion card 20 comprises a front end 201 and a rear end 202 opposite to the front end 201. A mounting piece 23 is attached to the front end 201. A flange 235, with a through hole 236, extends in a first direction from a first end of the mounting piece 23. A positioning piece 231, with a positioning hole 232, extends in a second opposite direction from a second end of the mounting piece 23. In one embodiment, the positioning piece 231 is substantially perpendicular to the mounting piece 23. An insertion port 211 is located on a bottom portion of the expansion card 20.

The mounting apparatus comprises a mounting case 30 and a securing member 40. The mounting case 30 comprises a bottom plate 31, a front plate 32, and a rear plate 33. In one embodiment, the front plate 32 and the rear plate 33 substantially perpendicularly extend from a front edge and a rear edge of the bottom plate 31, respectively. A circuit board (not shown) is located on the bottom plate 31, and a plurality of expansion slots 311 is located on the circuit board. A plurality of positioning posts 312 is located on the bottom plate 31 adjacent to the front plate 32.

A supporting piece 321 extends from a top edge of the front plate 32, and a plurality of fixing holes 323 is defined in the supporting piece 321. A plurality of receiving slots 322 is defined in the front plate 32.

A plurality of stopper pieces 331 and a pair of protrusions 332 are located on the rear plate 33. In one embodiment, each stopper piece 331 extends substantially perpendicular from an inner surface of the rear plate 33, and the protrusions 332 are located on the inner surface of the rear plate 33. Two fastening holes 334 are defined in the rear plate 33.

The securing member 40 comprises a plurality of limiting pieces 41 respectively corresponding to the plurality of stopper pieces 331. A pair of sliding slots 43 is defined in the securing member 40, and each of the sliding slots 43 comprises a sliding portion 431 and a receiving portion 432 communicating with the sliding portion 431. In one embodiment, each sliding slot 43 is substantially L-shaped, an extending direction of the sliding portion 431 is substantially perpendicular to an extending direction of the receiving portion 432. A pair of engaging holes 45 is defined in the securing member 40 respectively corresponding to the two fastening holes 334.

There are two fixing members 50 that respectively engage in the engaging holes 45. Each fixing member 50 comprises a fixing portion 51 and a spring 57. The fixing portion 51 comprises a head 511 and a fixing post 512 connected to the head 511. An engaging post 56 is secured to the fixing post 512, and a clasping hole 561 (see FIG. 1) is defined in the engaging post 56. The fixing post 512 extends through the clasping hole 561. In one embodiment, the engaging post 56 is elastic, and a diameter of the engaging post 56 is greater than a diameter of the engaging hole 45. An engaging slot 563 is defined in an outer portion of the engaging post 56. A first end of the spring 57 is engaged in the head 511, and a second end of the spring 57 is secured to the engaging post 56. When the fixing member 50 is secured to the securing member 40, the engaging post 56 is urged into the engaging hole 45 to engage an edge of the engaging hole 45.

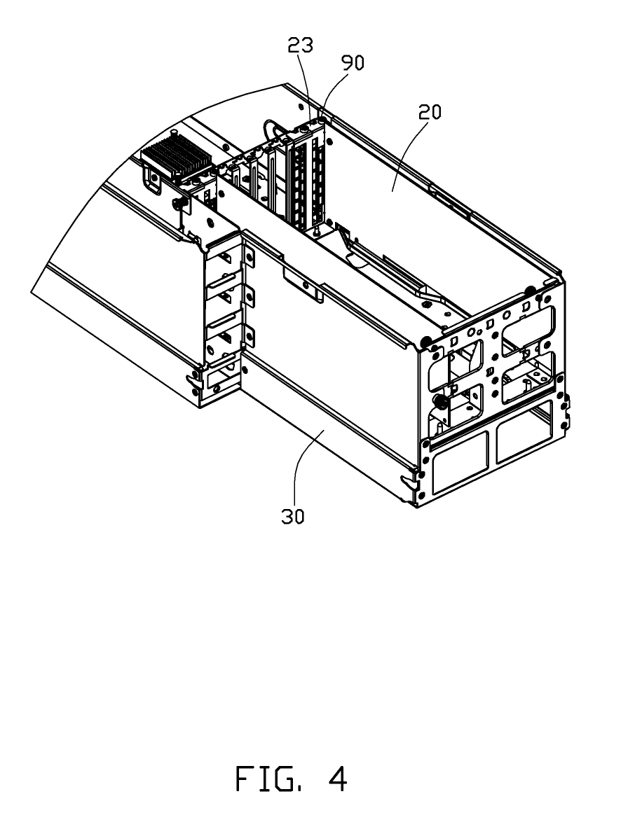

FIGS. 4-6 illustrate in assembly, the expansion card 20 is located in the mounting case 30, and the positioning hole 232 is aligned with the positioning post 312. The insertion port 211 is inserted into the expansion slot 311, and the positioning post 312 extends through the positioning hole 232. The flange 235 is placed on the supporting piece 321, and the through hole 236 is aligned with the fixing hole 323. A mounting member 90 is engaged in the through hole 236 and the fixing hole 323, to secure the flange 235 to the supporting piece 321. Therefore, the front end 201 is secured to the front plate 32, and the rear end 202 abuts one of the stopper pieces 331.

The pair of sliding slots 43 is aligned with the two protrusions 332, and each protrusion 332 is slid into the sliding portion 431. The fixing post 512 is slid towards the front plate 32 by the rear plate 33, and the spring 57 is extended to be deformed. The securing member 40 is slid in a direction that is substantially parallel to the rear plate 33, to engage the protrusions 332 in the receiving portions 432. When the fixing post 512 is aligned with the fastening hole 334, the spring 57 is released to engage the fixing post 512 in the fastening hole 334. Thus, the securing member 40 is secured to the rear plate 33, and the limiting piece 41 abuts a second side of the rear end 202. Therefore, the rear end 202 is stably sandwiched between the limiting piece 41 and the corresponding stopper piece 331.

In disassembly, the fixing portion 51 is pulled away from the rear plate 33, and the fixing post 512 is removed from the fastening hole 334. The securing member 40 is moved in a direction that is substantially parallel to the rear plate 33 to remove the protrusions 332 from the sliding slots 43. Thus, the securing member 40 is detached from rear plate 33. The mounting member 90 is disengaged from the flange 235. The expansion card 20 is moved up and out of the mounting case 30.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a mounting case comprising a front plate and a rear plate; and a stopper piece located on the rear plate;
a mounting piece attached to a front end of an expansion card and secured to the front plate; and
a securing member slidably attached to the rear plate and comprising a limiting piece;
wherein the securing member is slidable relative to the rear plate in a direction that is substantially parallel to the rear plate, and the limiting piece and the stopper piece are configured to sandwich a rear end of the expansion card therebetween.

2. The mounting apparatus of claim 1, further comprising a fixing member secured to the securing member, wherein the fixing member comprises a fixing portion, the fixing portion comprises a fixing post, the rear plate defines a fastening hole, and the fixing post is received in the fastening hole.

3. The mounting apparatus of claim 2, wherein the securing member defines an engaging hole, an engaging post is elastic and attached to the fixing post, and the engaging post is clipped to the engaging hole.

4. The mounting apparatus of claim 3, wherein an edge of the engaging hole is clipped into the engaging post.

5. The mounting apparatus of claim 3, wherein the engaging post defines a clasping hole, and the fixing post extends through the clasping hole.

6. The mounting apparatus of claim 3, wherein the fixing member further comprises a spring, the fixing portion further comprises a head connected to the fixing post, a first end of the spring is secured to the head, and a second opposite end of the spring is clipped to the engaging post.

7. The mounting apparatus of claim 1, wherein the securing member defines a sliding slot, and a protrusion is located on the rear plate and is slidably received in the sliding slot.

8. The mounting apparatus of claim 7, wherein the sliding slot is substantially L-shaped.

9. The mounting apparatus of claim 1, wherein a positioning piece extends substantially perpendicular from the mounting piece, a positioning hole is defined in the positioning piece, the mounting case further comprises a bottom plate, and a positioning post is located on the bottom plate and is engaged in the positioning hole.

10. The mounting apparatus of claim 1, wherein the stopper piece extends from an inner surface of the rear plate and substantially perpendicular to the rear plate.

11. A mounting apparatus comprising:
a mounting case comprising a front plate and a rear plate; and a stopper piece located on the rear plate, and a fastening hole defined in the rear plate;
a mounting piece attached to a front end of an expansion card and secured to the front plate;
a securing member slidably attached to the rear plate and comprising a limiting piece;
the limiting piece and the stopper piece configured to sandwich a rear end of the expansion card therebetween; and
a fixing member comprising a fixing portion and a spring secured to the fixing portion; the fixing portion engaged in the fastening hole;
wherein the spring is deformable to disengage the fixing portion from the fastening hole, and the securing member is slidable relative to the rear plate in a direction that is substantially parallel to the rear plate, to disengage from the rear plate.

12. The mounting apparatus of claim 11, wherein the securing member defines an engaging hole, the fixing portion comprises a fixing post, an engaging post is elastic and attached to the fixing post, and the engaging post is clipped to the engaging hole.

13. The mounting apparatus of claim 12, wherein an edge of the engaging hole is clipped into the engaging post.

14. The mounting apparatus of claim 12, wherein the engaging post defines a clasping hole, and the fixing post extends through the clasping hole.

15. The mounting apparatus of claim 12, wherein the fixing portion further comprises a head connected to the fixing post, a first end of the spring is secured to the head, and a second opposite end of the spring is clipped to the engaging post.

16. The mounting apparatus of claim 11, wherein the securing member defines a sliding slot, and a protrusion is located on the rear plate and is slidably received in the sliding slot.

17. The mounting apparatus of claim 16, wherein the sliding slot comprises a sliding portion and a receiving portion communicating with the sliding portion, and an extending direction of the sliding portion is substantially perpendicular to an extending direction of the receiving portion.

18. The mounting apparatus of claim 11, wherein a positioning piece extends substantially perpendicular from the mounting piece, a positioning hole is defined in the positioning piece, the mounting case further comprises a bottom plate, and a positioning post is located on the bottom plate and is engaged in the positioning hole.

19. The mounting apparatus of claim 11, wherein the stopper piece extends from an inner surface of the rear plate and substantially perpendicular to the rear plate.
